(19) United States
(12) Patent Application Publication
(10) Pub. No.: US 2010/0013045 A1
(43) Pub. Date: Jan. 21, 2010

(54) Method of Integrating an Element

(76) Inventor: Andrew Weeks, LB's-Hertogenbosch (NL)

Correspondence Address: PATTERSON & SHERIDAN, L.L.P., 3040 POST OAK BOULEVARD, SUITE 1500, HOUSTON, TX, 77056, US

(21) Appl. No.: 11/989,329

(22) PCT Filed: Aug. 7, 2006
(86) PCT No.: PCT/GB2006/002959

§ 371 Date: Jan. 13, 2009

(30) Foreign Application Priority Data
Aug. 5, 2005 (GB) 0516148.4

(51) Int. Cl. H01L 23/525; H01L 21/768

(52) U.S. Cl. 257/529; 438/601; 438/600; 257/530; 257/E21.592; 257/E23.149

(57) ABSTRACT

The present invention provides a method of integrating a structure, e.g. a fuse, for use in a semiconductor device, the method comprises several steps, the first step is providing a first layer of sacrificial material (1) on a substrate. The second step is providing the structure (5) on the first layer of sacrificial material, the structure having two terminal portions. The third step is providing a second layer of sacrificial material (3) over the first layer of sacrificial material and over a length of the structure between the terminal portions such that the length of the structure is surrounded by sacrificial material, said length defining a usable portion of the structure. The fourth step is providing a layer of dielectric material such that the first and second layers of sacrificial material and the structure are encased by the layer of dielectric material and the substrate. The fifth step is forming a passage through the dielectric material to provide access to the sacrificial material. The final step is injecting a fluid through the passage to remove the sacrificial material surrounding the usable portion of the structure, thereby defining a cavity in which the usable portion is suspended.

The present invention relates to a method of fabricating encapsulated fuse devices for use in, for example, the integration into Back End Of Line (BEOL) Complementary Metal Oxide Semiconductor (CMOS) devices for aluminium-based interconnects.

CMOS circuitry uses a combination of p-type and n-type metal-oxide-semiconductor field effect transistors (MOSFETs) and a plurality of other devices such as fuses, resistors and capacitors. The term CMOS also refers to the processes involved in the implementation of this circuitry. Typically, CMOS logic consumes less power and permits a higher component density than any other known logic. Therefore, microchips designed using CMOS processes are comparatively small and efficient. Because of these benefits, CMOS technology has become the dominant process in the industry of high-tech manufacturing.

Because of an increasing demand for smaller electronic devices, variations in CMOS processes have been developed in order to increase component density. These variations often include new and non-standard process steps and procedures. These new processes are often complicated and costly to implement. However, because CMOS processes have become an industry standard, CMOS design is somewhat rigid and does not always permit the most efficient use of space.

Therefore there is a clear need to find methods of, using known CMOS fabrication processes, integrating different components into the unused space in CMOS devices, thereby increasing component density, reducing semiconductor size and decreasing manufacturing costs.

In order to solve the problems associated with prior art methods, the present invention provides a method of integrating a structure for use in a semiconductor device, the method comprising the steps of:

providing a first layer of sacrificial material on a substrate;

providing the structure on the first layer of sacrificial material, the structure having two terminal portions;

providing a second layer of sacrificial material over the first layer of sacrificial material and over a length of the structure between the terminal portions such that the length of the structure is surrounded by sacrificial material, said length defining a usable portion of the structure;

providing a layer of dielectric material such that the first and second layers of sacrificial material and the structure are encased by the layer of dielectric material and the substrate;

forming a passage through the dielectric material to provide access to the sacrificial material; and

injecting a fluid though the passage to remove the sacrificial material surrounding the usable portion of the structure, thereby defining a cavity in which the usable portion is suspended.

Preferably, the structure is a fuse.

Preferably, the steps of providing a first and second sacrificial layer further comprise the step of:

depositing a layer of sacrificial material using Plasma-Enhanced Chemical Vapour Deposition.

Preferably, the step of providing the structure further comprises the steps of:

depositing a layer of conductive material onto the first layer of sacrificial material using a DC Magnetron reactive sputter process; and

patterning the deposited layer.

Preferably, the step of patterning the deposited layer further comprises the steps of: applying a photo-resist mask to the deposited layer;

etching the mask pattern into the deposited layer; and

removing the photo-resist mask layer.

Preferably, the conductive layer is a layer of Titanium Nitride (TiN).

Preferably, the fluid injected during the injecting step is a chlorine based etching fluid.

The present invention further provides a semiconductor device manufactured in accordance with the above method.

As will be apparent to the skilled reader, there are several advantages to the present invention. The fuse device structures are fully integrated into the CMOS device and are fabricated within the CMOS interconnect layers. Because the fuse structures are fabricated within the CMOS interconnect layers, the FEOL (Front End Of Line) transistor structures may be fabricated normally, and the complete process flow can be terminated by performing a standard CMOS anneal. This method therefore has little or no effect on the active CMOS (transistor) devices.

Also, this method can be used to fabricate different shapes of fuse element. Because the fuse elements are fabricated on a flat surface, there is no need for them to comprise vertical steps.

Furthermore, this method allows some degree of flexibility in the thickness of the sacrificial layers above and below the fuse element. Because a CMOS IMD4 oxide layer is used as the encapsulation layer for the fuse, no extra oxide deposition step is required to form the micro-encapsulation.

Moreover, because the silicon nitride passivation layer is also used to seal the release etch holes in the encapsulation layer, no extra deposition step is required to seal the micro-encapsulation cavities.

What is more, this method requires a small number of extra masking steps and a small number of extra process steps.

Finally, because the method of the present invention does not require difficult new process steps, it is relatively straightforward to implement and run in a CMOS wafer fabrication process.

An example of the present invention will now be described with reference to the accompanying drawings, in which:

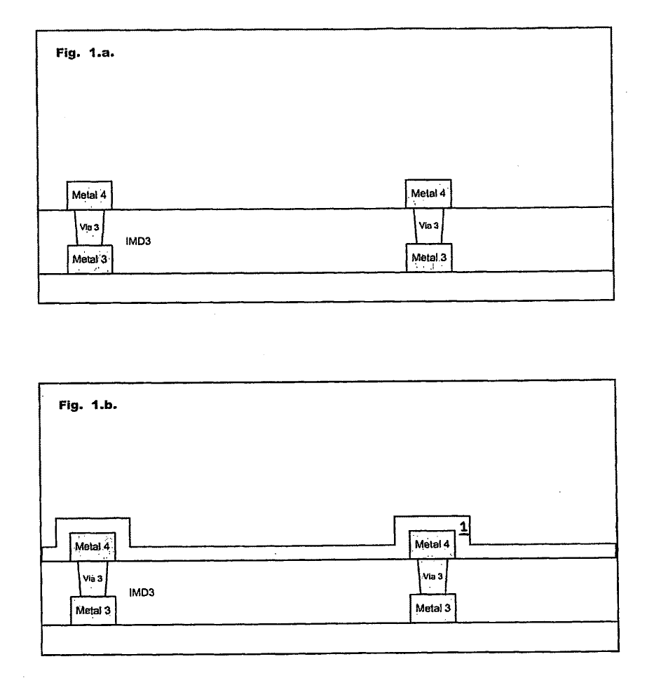

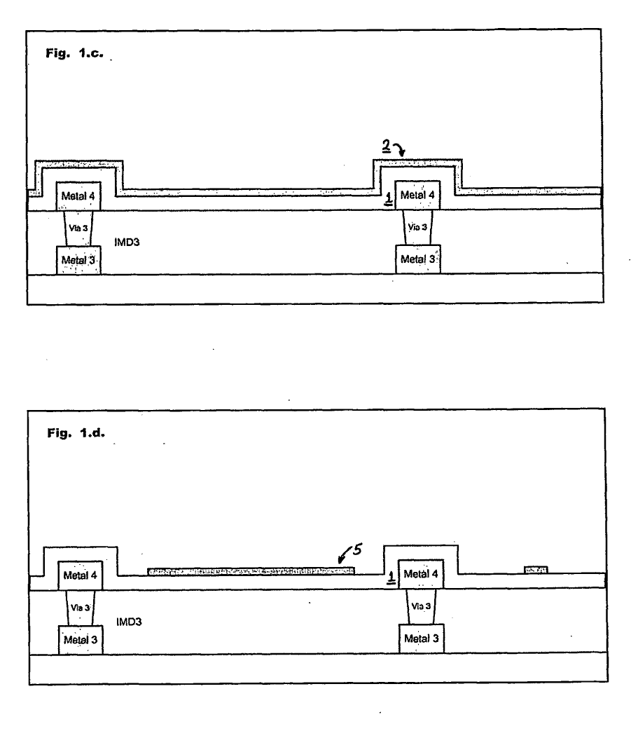

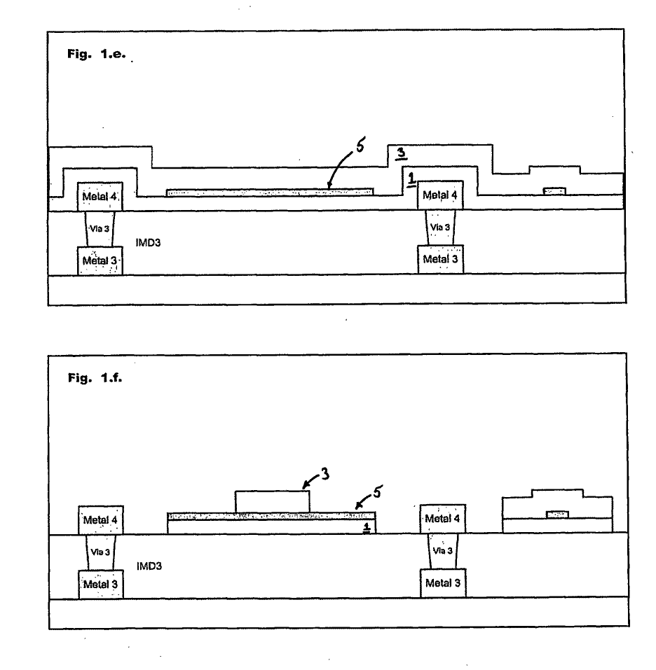

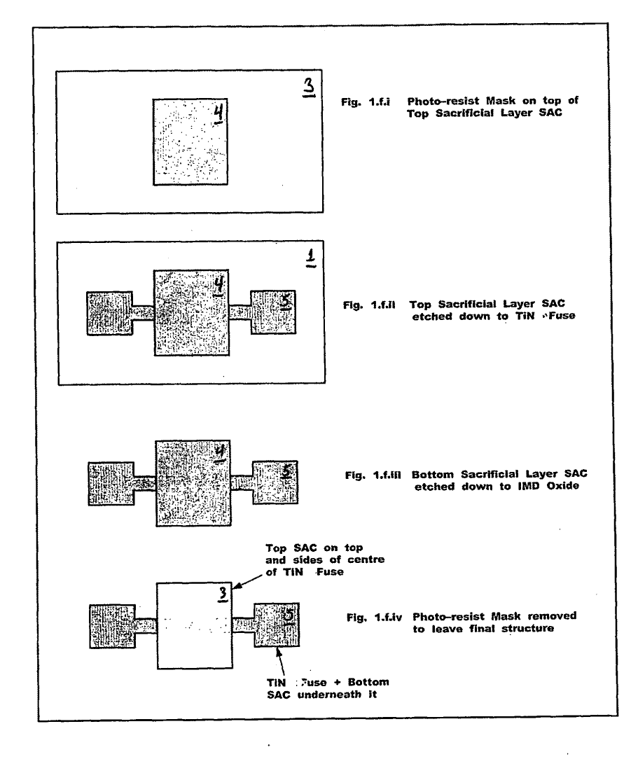

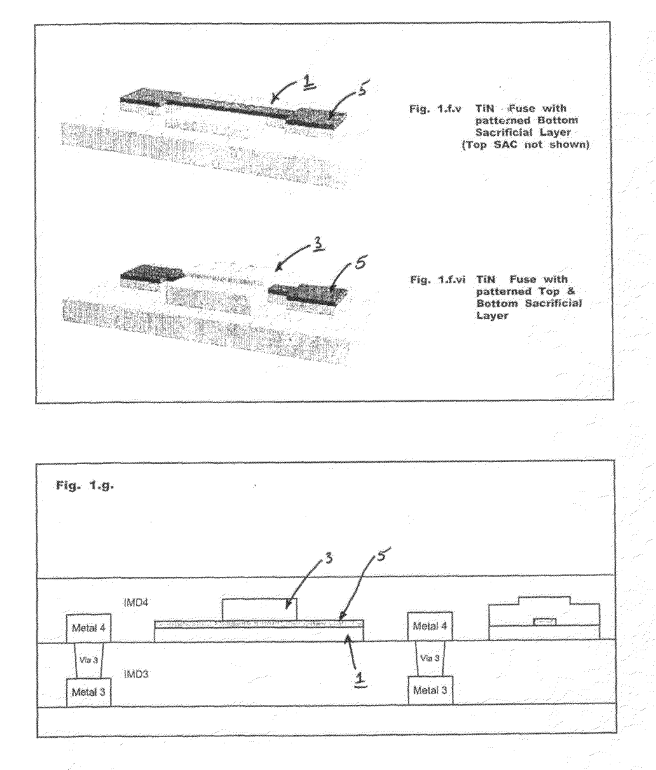

FIG. 1a shows a diagram representing the result of the first step of a method in accordance with one embodiment of the present invention;

FIG. 1b shows a diagram representing the result of the second step of a method in accordance with one embodiment of the present invention;

FIG. 1c shows a diagram representing the result of the third step of a method in accordance with one embodiment of the present invention;

FIG. 1d shows a diagram representing the result of the fourth step of a method in accordance with one embodiment of the present invention;

FIG. 1e shows a diagram representing the result of the fifth step of a method in accordance with one embodiment of the present invention;

FIG. 1f shows a diagram representing the result of the sixth step of a method in accordance with one embodiment of the present invention;

FIG. 1fi shows a diagram representing the result of the first sub-step of the step of FIG. 1f;

FIG. 1fii shows a diagram representing the result of the second sub-step of the step of FIG. 1f;

FIG. 1fiii shows a diagram representing the result of the third sub-step of the step of FIG. 1f;

FIG. 1fiv shows a diagram representing a complete fuse element with both sacrificial layers on a base of oxide;

FIG. 1fv shows a diagram representing the complete fuse element having the top sacrificial layer removed so that the shape of the TiN fuse element and the first sacrificial layer can be seen;

FIG. 1g shows a diagram representing the result of the seventh step of a method in accordance with one embodiment of the present invention;

FIG. 1h shows a diagram representing the result of the eighth step of a method in accordance with one embodiment of the present invention;

FIG. 1i shows a diagram representing the result of the ninth step of a method in accordance with one embodiment of the present invention;

FIG. 1j shows a diagram representing the result of the tenth step of a method in accordance with one embodiment of the present invention;

FIG. 1k shows a diagram representing the result of the eleventh step of a method in accordance with one embodiment of the present invention; and

FIG. 1l shows a diagram representing the result of the twelfth step of a method in accordance with one embodiment of the present invention.

The present invention describes a method of fabricating a fuse device integrated into a 0.35 μm CMOS with 5 levels of metal interconnects based on aluminium and CMP planarization of the Inter-Metal Dialectric (IMD) oxide layers between the metal interconnect layers. In reference to FIGS. 1a to 1l, a first embodiment of the present invention will now be described.

The first step in the method is shown in FIG. 1a. The first step consists of fabricating a CMOS silicon wafer using standard CMOS process flows used to fabricate 0.35 μm technology devices with five levels of aluminium metal interconnects.

In this example, the silicon wafers are processed up to and including the patterning of the CMOS Metal4 layers, including Metal4 etch and resist strip and any cleans or post-treatments that are normally required after Metal4 etch. Up to this point, all the process steps have been standard process steps used in the fabrication of 0.35 μm CMOS technology.

The top surface of the wafer is a CMOS IMD3 oxide layer which has been planarized by CMP (Chemical Mechanical Polishing). On the oxide surface has been provided with patterned lines of CMOS Metal4. The typical height of these CMOS Metal4 lines is 0.7 μm. The main part of these metal lines will be approximately 0.6 μm of aluminium alloy, typically aluminium/copper (Al/Cu) or aluminium/silicon/copper (Al/Si/Cu).

Below the aluminium, there is a barrier layer of approximately 100 nm of titanium nitride (TIN). Alternatively, there could be 80 nm of TiN on top of 20 nm of titanium (Ti).

Over the aluminium alloy metal, there may be a layer of titanium nitride, which was originally an ARC (Anti-Reflection Coating) layer approximately 30 nm thick. This TiN ARC layer may have been heavily oxidized, thinned down, or may have been completely removed.

In reference to FIG. 1b, the second step in the method according to one embodiment of the present invention will now be described. The second step comprises providing a first sacrificial layer 1 by depositing onto the top surface of the structures described in the first step. This first sacrificial layer 1 (conformably) covers the top surface of the CMOS IMD3 layer, and all the exposed surfaces (top, side-walls, ends) of the CMOS Metal4 features on the top surface of the CMOS silicon wafer.

The material used for the first sacrificial layer 1 is preferably be PECVD (Plasma-Enhanced Chemical Vapour Deposition) silicon nitride. It may be possible to use a standard silicon nitride deposition process that is already available in a CMOS fabrication process which is being used for the rest of the semiconductor device. However, it will usually be necessary to develop a new deposition recipe that will provide the material properties required.

As this layer will form the first sacrificial layer 1, the thickness of this layer should be selected to permit the fuse device to function optimally. The required thickness is typically be in the range 200-600 nm.

In reference to FIG. 1c, the third step in the method according to one embodiment of the present invention will now be described. The third step comprises providing a conductive layer 2 by depositing it onto the top surface of the first sacrificial layer 1 provided in the second step. This conductive layer 2 will then be patterned to form the fuse element. It is therefore important that this conductive layer 2 have all the properties required for the fuse element 5. Thus, the material must be conductive, must have a relatively high resistivity, high mechanical strength, and must be a material that is commonly available in CMOS wafer fabrication processes, and for which a deposition technique exists that allows it to be deposited and patterned without adversely affecting any underlying CMOS circuitry.

In this embodiment, the material used for the conductive layer 2 is TiN (Titanium Nitride), deposited by a DC Magnetron reactive sputter process. This deposition process can be done in many different types of PVD system. It may be possible to use a standard TiN deposition process that is already available in the CMOS Fabrication process, but it will probably be necessary to develop a new deposition recipe that will provide the TiN material properties required.

As the conductive layer 2 will form the element of the fuse structure 5, the thickness of the conductive layer 2 should be selected to ensure optimal functioning of the fuse element. The required thickness could be in the range 50-150 nm.

In reference to FIG. 1d, the fourth step in the method according to one embodiment of the present invention will now be described. The fourth step comprises the step of providing a fuse structure 5 by patterning the conductive layer 2 to form a TiN fuse element. The fuse structure 5 is thus provided by combining the third and fourth steps. The patterning is done by the usual technique of applying a photo-resist mask, etching the mask pattern into the conductive layer 3, and then removing the photo-resist mask layer. This is the first of the three extra mask layers required to implement this method.

As the material used for the conductive layer 2 is TiN (Titanium Nitride), the etch process used to pattern it will be the standard process used to etch TiN in the CMOS Fabrication process. This will normally be an etch process based on chlorine (e.g CL2/BCL3 or CL2/BCL3/N2 are commonly used). This process can be done satisfactorily in a high density dual RF source plasma reactor or a medium density (RIE) plasma reactor with a single RF source. Because TiN is normally etched as part of a multi-layer stack containing a layer of aluminium alloy with TiN above it and a TiN/Ti layer below it, the standard process used to etch this metal stack in a CMOS wafer fabrication process may need to be modified to produce an etch process suitable for a layer containing only TiN.

After plasma etch of the TiN, the photo-resist mask and the side-wall etch polymer material that is formed during the anisotropic TiN etch will be removed. The standard resist strip and polymer removal treatment that is used after metal etch in the CMOS fabrication process can be used for this. Other methods of resist strip and polymer removal can also be used, and the process may be specially chosen to introduce the minimum amount, or a controlled amount, of differential stress into the TiN fuse structure 5. At the end of this step the TiN fuse structure 5 will have been patterned. It will therefore be situated on top of the first sacrificial layer 1. At this point it is not electrically connected to any other structure.

Now, in reference to FIG. 1e, the fifth step in the method according to one embodiment of the present invention will now be described. The fifth step comprises providing a second layer of sacrificial material by depositing a second sacrificial layer 3 onto the TiN fuse structure 5 and first sacrificial layer 1. This second sacrificial layer 3 (conformally) covers the top and side surfaces of the TiN fuse structure 5, and the first sacrificial layer 1. The second sacrificial layer 3 will become the sacrificial layer above the element (or fusible portion) of the fuse structure 5. The material used for the second sacrificial layer 3 could be PECVD (Plasma-Enhanced Chemical Vapour Deposition) silicon nitride. Again, it may be possible to use a standard silicon nitride deposition process that is already available in the CMOS Fabrication process. However, it will typically be necessary to develop a new deposition recipe that will provide the material properties required. It is expected that the deposition process will be the same as (or very similar to) the process used to deposit the first sacrificial layer 1 in the second step.

As this layer will form the second sacrificial layer 3, the thickness of this layer should be selected to permit the element of the fuse structure 5 to function optimally. The required thickness could be in the range 400-1000 nm. At the end of this step the TiN usable (i.e. fusible) portion of the fuse structure 5 will be completely enclosed within sacrificial layer material.

In reference to FIG. 1f, the sixth step in the method according to one embodiment of the present invention will now be described. The sixth step comprises patterning the sacrificial layers.

The patterning is done by the usual technique of applying a photo-resist mask 4, etching the sacrificial layer material, and then removing the photo-resist mask layer. This is the second of the three extra mask layers required to implement this method.

The etch process used to pattern the sacrificial layer silicon nitride can be based on a standard process used to etch silicon nitride in the CMOS Fabrication process, but there are special requirements that must be met. Examples of such a process could be a process normally used to etch bond pads into passivation silicon nitride, or a process normally used to etch silicon nitride for a LOCOS or Poly-Buffered LOCOS. process.

This etch process can be performed using a variety of different types of plasma etch equipment. The etch process can be considered to proceed in three steps, each with different requirements. FIG. 1f shows a layout view of the fuse structure before the etch. A rectangle of photo-resist sits on the second sacrificial layer 3.

In the first step of the etch process, the photo-resist mask 4 acts as an etch mask as the second sacrificial layer 3 is etched away from the top of the TiN fuse until the top surface of the TiN fuse is exposed, as shown in FIG. 1fii. In the second step of the etch process, the TiN fuse acts as an additional etch mask as the first sacrificial layer 1 is etched away. Sacrificial layer material that is not covered by TiN or the photo-resist mask 4 is etched away until the oxide (the top surface of CMOS IMD3) and metal (the CMOS Metal4) surfaces under the first sacrificial layer 1 are exposed, as shown in FIG. 1fiii. Sacrificial layer material under the photo-resist mask 4 or under the TiN fuse material is not etched away and remains. It is important that this second step of the etch process removes the smallest amount of TiN fuse material possible.

The third step of the etch process is an extension of the second step and is used to remove any residual sacrificial layer material that should be removed at this time. In particular, any residual sacrificial layer materials on the sides of the CMOS Metal4 lines will be removed during this step. FIG. 1fiii shows the layout view of the remaining structure at the end of this etch step. This third step of the etch process should remove the least possible amount of TiN fuse material and IMD3 oxide material. After the etch process has been completed, the photo-resist mask 4 is stripped off with a conventional resist strip process, to leave the structure shown in layout view in FIG. 1fiv, and in the 3-D view in FIG. 1fvi.

FIG. 1fv and FIG. 1fvi show a 3-D view of the fuse structure. FIG. 1fvi shows the complete fuse structure 5 with both sacrificial layers on a base of oxide. FIG. 1fv shows the complete fuse structure 5, but with the second sacrificial layer 3 removed so that the shape of the TiN fuse element and the first sacrificial layer 1 can be seen.

At the end of this step the complete TiN fuse element with sacrificial layers will have been fabricated. At this point it is not electrically connected to any other structure. The TiN fuse element is a long narrow strip of TiN material. At both ends of the TiN fuse element, there is a large square pad. This pad will later be contacted from above by a via structure. Under the whole length of the TiN fuse structure 5, there is sacrificial layer material. Above the centre of the TiN fuse, there is an additional rectangle of second sacrificial layer 3 material (as shown in FIG. 1fvi), and where this rectangle of second sacrificial layer 3 material exists, there is also sacrificial material directly beneath it (as shown in FIG. 1fv).

The fuse structure 5 therefore comprises a fuse element, which is an elongate straight narrow strip of TiN material with connection pads at each end. The central part of this fuse element is completely surrounded by sacrificial layer material. This whole structure will next be enclosed within an encapsulation oxide. When the sacrificial layer material is removed later in the fabrication process, it will leave a free-standing section of TiN fuse material within an empty cavity that will partially have the interior shape that the exterior of the combined first and second sacrificial layers have as a result of this step. The section of TiN fuse element that is free-standing within the cavity will be approximately 3.0-4.0 μm long, 0.4 μm wide, and 50-150 nm thick. This is the section of fuse device that can be blown as a fuse and is therefore the programmable element of the fuse device.

Now, in reference to FIG. 1g, the seventh step of the method according to one embodiment of the present invention will now be described. The seventh step comprises providing a layer of dielectric material by depositing and planarizing a layer of CMOS IMD4.

This oxide is deposited using the standard oxide deposition process used for the CMOS IMD4 layer. The CMP planarization is the standard CMP (Chemical Mechanical Polishing) used in the normal CMOS process flow. Any clean or post-treatment normally required after CMP planarization will be done as normal.

After this step, the degree of planarization of the top surface of the CMOS IMD4 oxide will be the same as normal in the CMOS process flow. The final thickness of planarized oxide on top of the CMOS Metal4 features is approximately 0.9 μm, and directly above the CMOS IMD3 (in areas where there is no CMOS Metal 4 and no fuse device structure) the final thickness of planarized oxide will be approximately 1.6 μm. In addition to being the CMOS IMD4 oxide layer, this planarized oxide layer also forms the micro-encapsulation structure for the fuse device.

In reference to FIG. 1h, the eighth step in the method according to one embodiment of the present invention will now be described. The eighth step comprises the formation of a passage in the dielectric material layer by forming a CMOS Via 4 and the Fuse Via.

The patterning is done by the usual technique of applying a photo-resist mask, etching the via mask pattern into CMOS IMD4 oxide layer, and then removing the photo-resist mask layer. The CMOS Via 4 features and the Fuse Via features are combined onto one single mask and both types of via are formed at the same time. The photo-lithography process to pattern the via features in the photo-resist can typically be done using standard processes that are used to pattern CMOS Via 4 features. However, any significant difference between the thickness of oxide being exposed on top of the TiN fuse elements and the thickness of oxide on top of the CMOS Metal4 lines, or a difference between the reflectivity of the top surface of the TiN fuse elements and the top surface of the CMOS Metal4 lines, may require some adjustment in the lithography process to provide an exposure that is appropriate for both types of via.

If the thickness of oxide on top of the TiN fuse element is similar to the thickness of oxide on top of the CMOS Metal4 lines, the standard CMOS Via 4 etch process may be used to etch open both the CMOS Via 4 and the Fuse Via.

However, if the thicknesses are different, the CMOS Via 4 etch process will need to be modified. Additional modification to the via etch process may also be necessary to make sure that it etches the minimum amount possible into the top of the TiN fuse element.

After plasma etch of the vias, the photo-resist mask and the etch polymer material that is formed during the via etch will be removed. The standard resist strip and polymer removal treatment that is used after a via etch in the CMOS fabrication process can be used for this step.

The CMOS Via 4 holes can be circular with a nominal diameter of approximately 0.4 μm and a depth of 0.9 μm.

At the end of this step, vias that allow electrical contact to the TiN fuse elements and to the CMOS Metal4 features will have been formed. The next step will be to connect these using tungsten via plugs and CMOS Metal 5.

In reference to FIG. 1i, the ninth step in the method in accordance with one embodiment of the present invention will now be described. The ninth step comprises depositing and patterning the CMOS Metal5 in order to connect the TiN fuse structure and the CMOS Metal4.

This is a multi-step procedure which comprises process sub-steps that are part of a standard CMOS process flow. The first of these sub-steps is the deposition of the Ti/TiN barrier layer (with sputter etch before Ti/TiN deposition). The second sub-step is the deposition of the Tungsten plug. The third sub-step is the etching-back of the Tungsten plug. The fourth sub-step is the deposition of Metal5 aluminium. The fifth sub-step is the deposition of Metal5 TIN ARC and the fifth and final step is the patterning of the Metal 5 (which includes Metal5 lithography, Metal5 etch and resist/polymer strip).

Most of these process steps will be the standard process steps that are used in CMOS technology, but some steps may need to be modified slightly. If the Fuse Via shape and size is different from that of the CMOS Via 4 holes, then the CVD tungsten deposition process that deposits tungsten plug material inside the via holes may need to be modified in order to improve the filling of the Fuse Via holes with tungsten material. If the tungsten deposition needs to be modified, then it is possible that the tungsten etch-back process may also need to be slightly modified. Any modification required is expected to be minor. There should be no need to modify any of the other CMOS process steps in this group.

The CMOS Metal 5 lines formed by this group of process steps will have a total height of approximately 1.0 μm and a minimum width of 0.8 μm. The main part of these metal lines will be a approximately 0.9 μm of aluminium alloy, probably aluminium/copper (Al/Cu), but possibly aluminium/silicon/copper (Al/Si/Cu).

Below the aluminium, there should be a barrier layer of approximately 100 nm titanium nitride (TiN). However, this could possibly be 80 nm of TiN on top of 20 nm of titanium (Ti). On top of the aluminium alloy metal there may be a layer of titanium nitride, which was originally an ARC (Anti-Reflection Coating) layer approximately 30 nm thick. This TiN ARC layer may have been heavily oxidized, thinned down, or may have been completely removed.

At the end of this group of process steps, the structure will appear as in the cross-section view of FIG. 1i. The complete TiN fuse structure including sacrificial layers will be embedded into the CMOS IMD4 oxide layer, which forms the encapsulation layer for the fuse structure. The ends of the TiN fuse element will be electrically connected to the CMOS circuitry through tungsten plugs (with TiN barrier) in the Fuse Via connecting to CMOS Metal5.

Now, in reference to FIG. 1j, the tenth step in the method according to one embodiment of the present invention will now be described. The tenth step comprises patterning Release Etch Holes into the CMOS IMD4 layer.

These release etch holes will provide access to the sacrificial layers to allow the release etch to remove the sacrificial layers from around the fuse device. The patterning is done by the usual technique of applying a photo-resist mask, etching the CMOS IMD4 oxide layer, and then removing the photo-resist mask layer. This is the third of the three extra mask layers required to implement this method.

The lithography process will be very similar to the process used to form vias. The release hole etch process will also be similar to a via etch process. The release hole dimensions are expected to be similar to those of a via, with a width of approximately 0.4 μm, and a depth of 0.5-0.9 μm.

In reference to FIG. 1k, the eleventh step in the method according to one embodiment of the present invention will now be described. The eleventh step comprises removing sacrificial material by Release Etching the sacrificial layers from around the usable (i.e. fusible) portion of the fuse structure 5.

This is a special isotropic plasma etch process. This process may not be previously available in a standard CMOS wafer fabrication process. However, most standard CMOS wafer fabrication processes will have plasma etch process equipment in which a suitable release etch process can be established. The release etch process can be done satisfactorily in a high density dual RF source plasma reactor, or a medium density plasma reactor with a single RF source, or a down-stream plasma etch system. The release etch process requires a sufficiently high density of fluorine radicals to remove the silicon nitride sacrificial layer material at a suitable rate. SF6 or NF3 gas can conveniently be used as the fluorine source gas.

A plasma is used to generate fluorine radicals. These pass through the release etch hole and react with the silicon nitride sacrificial layers to etch away the sacrificial layer materials. The etch products pass out of the release etch hole and are pumped away. In this manner, the sacrificial layers can be completely, or partially, etched away.

FIG. 1k shows the complete removal of the sacrificial layers and FIG. 1ki shows a partial removal of the sacrificial layers. In the case of a partial release etch, the silicon nitride sacrificial layer material that remains will be under the ends of the TiN fuse element, as these are the locations furthest away from the release etch hole.

The purpose of the release etch is to remove the silicon nitride sacrificial layer material. Ideally, the release etch will not remove any other material. The materials and device structures that are exposed to the release etch plasma and which should not be removed and should not be changed are the TiN of the fuse structure 5, the oxide of the CMOS IMD4 layer (including the sides of the release etch hole and the interior of the cavity), the oxide of the CMOS IMD3 layer on the bottom of the cavity beneath the fuse element and all parts of the conducting interconnect layers (including all the materials comprising the CMOS Metal5). To achieve this, it may be necessary that the main part of the CMOS Metal5 be made of aluminium with a small addition of copper, instead of an alloy of aluminium with small amounts of both copper and silicon that is sometimes used in CMOS technology. In addition, it is important that the release etch process does not introduce a significant amount of stress into one or more surfaces of the TiN element of the fuse structure 5 and thereby cause the TiN element to bend and to touch another surface either during the release etch, or during any subsequent process step, or later when the TiN element is being ‘blown’ as a fuse element. These requirements can be achieved by special adjustment and control of the release etch conditions.

After the release etch, a special post-treatment may be performed to modify the surfaces of the TiN element. This treatment may also be used to control or modify any differential stress that has been introduced into the fuse structure 5 by one or more of the process steps used to manufacture the complete fuse device integrated into CMOS.

At the end of this stage, all the silicon nitride sacrificial layer material that had been surrounding the fusible part of the TiN element will have been removed. This will leave the centre section of the TiN fuse free-standing inside an empty cavity formed within the CMOS IMD 4 oxide. The fuse structure 5 will be supported only at the ends.

The free-standing section of TiN fuse element can be blown as a fuse. This the programmable element of the fuse device.

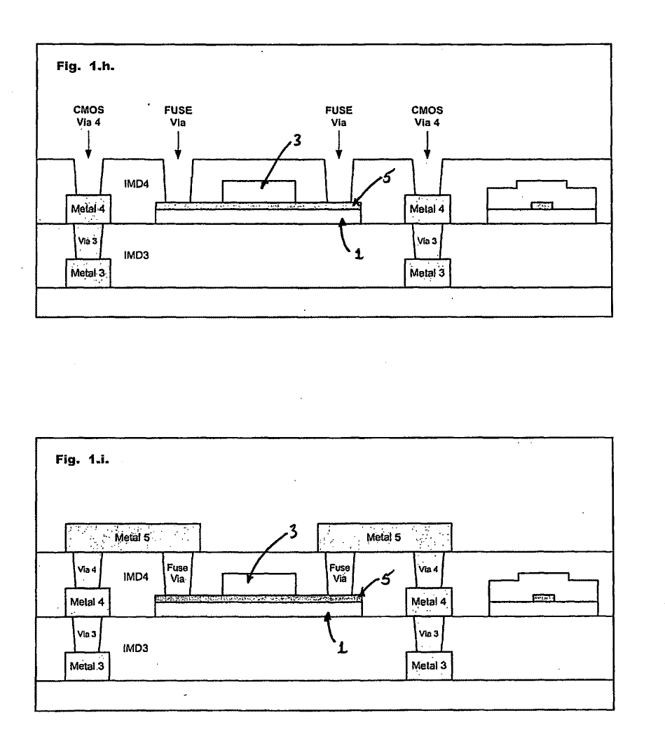

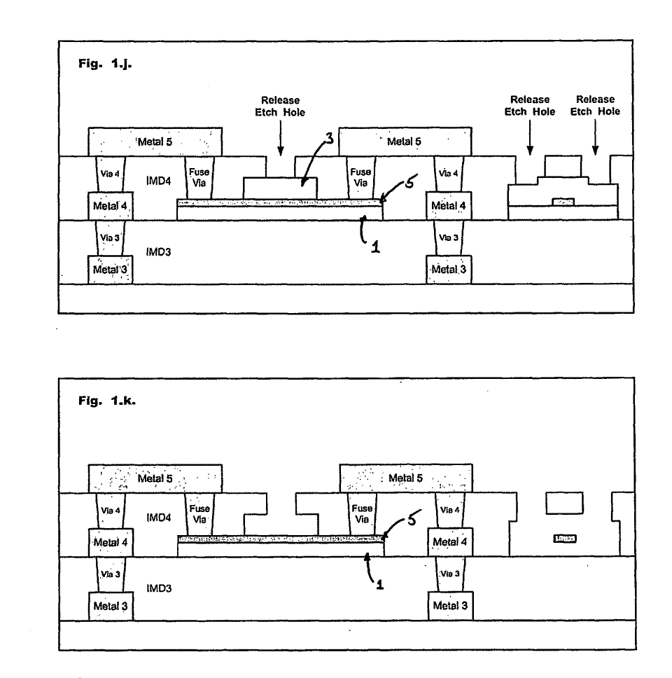

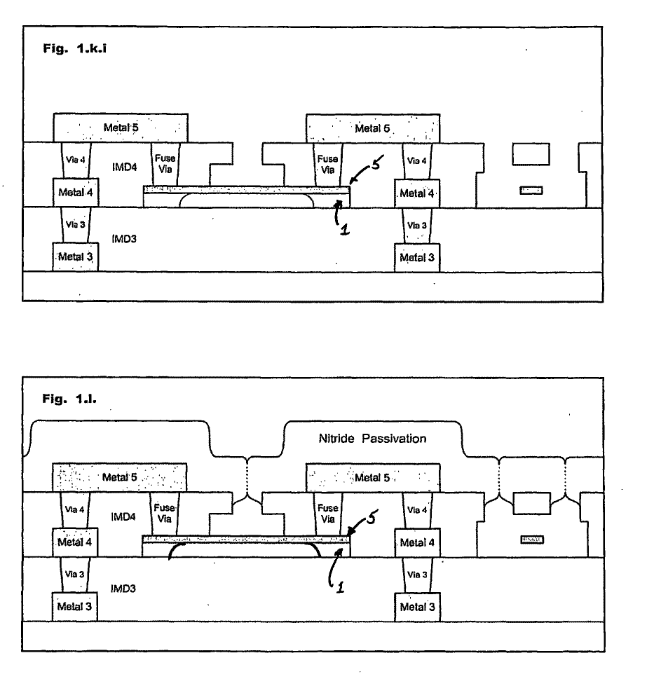

Now, with reference to FIG. 11, the twelfth step in the method in accordance with one embodiment of the present invention will be described. The twelfth step includes depositing a silicon nitride passivation layer and to close and seal the release etch holes. This seals the free-standing TiN element inside a cavity.

For this process step, it may be possible to use the standard PECVD silicon nitride deposition process that is normally used to deposit the silicon nitride passivation layer onto CMOS wafers. However, it may be necessary to modify the standard silicon nitride deposition process to meet the special requirements for hole sealing.

The requirements for the deposition that will seal the release etch holes are that the deposition will form on the sides and top of the release etch hole until a complete layer is formed. The integrity of the film deposited over a release hole should be equivalent to that of a standard silicon nitride passivation layer so that adequate protection is provided for the CMOS circuitry below the fuse device.

A minimum amount of silicon nitride material (preferably none at all) should be deposited inside the cavity, and no material should be deposited on the TiN fuse element itself. In order to achieve these requirements, it may be necessary to first deposit an additional layer of a different material (e.g. a PECVD Oxide), and then a layer of PECVD silicon nitride, or to significantly increase the thickness of the silicon nitride passivation layer. If the passivation deposition is modified, it is important that the layer or layers deposited to seal the release etch holes still function adequately as a passivation layer for the CMOS devices.

At this stage, the special process steps required to fabricate the fuse device in BEOL CMOS have been completed. The silicon wafer now continues through the remaining standard CMOS process steps. This requires patterning of the bonding pads. If the thickness of the silicon nitride passivation deposition done in the twelfth step has been increased to improve the sealing of the release etch holes, then the pad etch process will need to be modified. After patterning of the bonding pads and removal of the photo-resist, a CMOS anneal is done. This is accomplished using the standard anneal process that is normally the last process done before silicon wafers are shipped out of the CMOS wafer fabrication process.

After completion of the CMOS anneal, the manufacturing process described above will have fabricated a complete CMOS micro-electronic device which contains all the normal CMOS circuit capability plus a fuse device structure embedded between the CMOS metal interconnect layers.

The core of the fuse device structure is a free-standing fuse element fabricated using titanium nitride. This TiN element is contained within a cavity of oxide of silicon which is formed by the top of the CMOS IMD3 oxide layer on the bottom of the cavity, and the bottom of the CMOS IMD4 oxide layer on the top and sides of the cavity. A release etch hole in the cavity is sealed by a deposition of silicon nitride. The free-standing TiN element is supported at each end by a section of TiN connected to CMOS IMD4 oxide above it and by Fuse Via structures that are similar to CMOS Via 4. Electrical connections to the TiN fuse element are made through the Fuse Via, which connect through tungsten via plugs to lines of CMOS Metal 5.

The normal CMOS metal interconnect layers can be used to make an electrical connection between the fuse device structure and CMOS driver circuitry, which can be fabricated in silicon below the fuse structure. The CMOS circuitry can be designed so that a transistor is able to apply a step function of voltage across the two ends of the TiN fuse element. This causes a pulse of current to flow through the TiN fuse element. The current flowing through the TiN fuse element causes the fuse element to heat up and because the resistivity of the TiN fuse material is relatively high, a significant amount of heat energy is generated in the TiN fuse element. Because the TiN fuse element is free-standing (the central section of the TiN fuse element does not touch any other solid material), very little of this heat can be removed by conduction, so the temperature of the fuse element can become very high. If the CMOS driver circuitry is designed to apply a pulse of current that generates sufficient heat to drive the temperature of the fuse element above the melting point of the TiN material from which it is fabricated, then the TiN fuse element will ‘blow’ like a typical fuse. Any material evaporating from the TiN fuse as it heats and ‘blows’ will be contained within the cavity.

Before the fuse is blown, a small electrical current can be passed through the TiN fuse element without significantly modifying the fuse, and this current flow can be detected. After the fuse is ‘blown’, no current can flow. This change in state from the ability to pass a current to no ability to pass a current, is irreversible. The complete fuse device, consisting of the TiN fuse element fabricated as part of the fuse device structure and controlled by CMOS driver circuitry, can therefore function as an OTP (One Time Programmable) memory device.

The above is one embodiment of the present invention. The above embodiment creates a device which has specific features. Firstly, the fuse device is positioned at the level of CMOS Metal4. Secondly, the sacrificial layers below and above the fuse element are relatively thin. Thirdly, the special vias that connect the fuse to Metal 5 are fabricated at the same time and with the same patterning process that is used to pattern the CMOS Via 4 features which connect CMOS Metal5 to CMOS Metal4. Fourthly, the CMOS IMD4 layer is used as the encapsulation layer for the fuse device. Finally, the silicon nitride passivation layer that is normally used as passivation for the CMOS micro-electronics circuitry is used to seal the release etch hole in the encapsulation layer.

It is understood that the present invention may equally be applied to other encapsulated links or non-movable micromechanical elements such as a fuses, switch elements or other charge transfer elements operable within a cavity.

All the dimensions quoted in the preferred embodiment are dimensions that are used in 0.35 μm CMOS technology. However, this method can readily be adapted to fabricate fuse devices in any similar aluminium-based CMOS technology. This includes most CMOS technologies between 0.35 μm and 0.18 μm and some CMOS technologies in the ranges 0.6-0.35 um and 0.18-0.13 μm.

This invention describes a version for 0.35 μm CMOS technology with five levels of aluminium interconnect metal and CMP (Chemical Mechanical Polishing) planarization. This method can also be adapted for other CMOS technology nodes which use a similar interconnect technology.

It can also be used for CMOS technologies in which the number of aluminium-based interconnect metal layers is different from the 5 levels that are normally used in 0.35 μm technology. In addition, it can be adapted for use in older technologies in the range 1.0 μm to 0.35 μm with Spin-On Glass (SOG) planarization and 3 levels of aluminium-based interconnect.

Also, the preferred embodiment includes CMOS with 5 levels of aluminium metal interconnect. If this method is used to fabricate fuse devices in a CMOS technology with a different number of aluminium-based interconnect metals, then all references to Metal5 in this description will refer to the top level of metal in the CMOS technology, and all references to Metal4 in this description shall refer to the next-to-top level of metal in the CMOS technology.

Other possible variations of this method exist. For example, the fuse structure can be fabricated at a lower level in the CMOS interconnect structures. This means placing it at the level of CMOS Metal5. This would offer the benefit of allowing a thicker sacrificial layer above the TiN fuse element.

Moreover, directly after etching the TiN fuse element as shown in FIG. 1d, the first sacrificial layer 1 may be etched, using the TiN fuse mask as the etch mask. Use of this variation may have the advantage of allowing an easier implementation of the sacrificial layer patterning etch process, shown in FIG. 1f.

Furthermore, both the top and first sacrificial layer 1 s may be left intact and not patterned. This variation has the advantage of requiring one less masking step and one less etch step. The two variations (etching the first sacrificial layer 1 after TiN fuse etch and not including patterning of the second sacrificial layer 2) may be combined. This last variation also has the advantage of requiring one less masking step and one less etch step. Preferably, the method of the present invention will be used with a fuse manufactured by Cavendish Kinetics Limited under the name “eFuse”.

1. A method of integrating a structure for use in a semiconductor device, the method comprising the steps of:
providing a first layer of sacrificial material on a substrate; providing the structure on the first layer of sacrificial material, the structure having two terminal portions;
providing a second layer of sacrificial material over the first layer of sacrificial material and over a length of the structure between the terminal portions such that the length of the structure is surrounded by sacrificial material, said length defining a usable portion of the structure;
providing a layer of dielectric material such that the first and second layers of sacrificial material and the structure are encased by the layer of dielectric material and the substrate;
forming a passage through the dielectric material to provide access to the sacrificial material; and
injecting a fluid though the passage to remove the sacrificial material surrounding the usable portion of the structure, thereby defining a cavity in which the usable portion is suspended.

2. The method of claim 1, wherein the structure is a fuse.

3. The method of claim 1, wherein the steps of providing a first sacrificial layer and a second sacrificial layer further comprise the step of:
depositing layers of sacrificial material using Plasma-Enhanced Chemical Vapour Deposition.

4. The method of claim 1, wherein the step of providing the structure further comprises the steps of:
depositing a layer of conductive material onto the first layer of sacrificial material using a DC Magnetron reactive sputter process; and
patterning the deposited layer.

5. The method of claim 4, wherein the step of patterning the deposited layer further comprises the steps of:
applying a photo-resist mask to the deposited layer;
etching the mask pattern into the deposited layer; and
removing the photo-resist mask layer.

6. The method of claim 4, wherein the conductive layer is a layer of Titanium Nitride (TiN).

7. The method claim 1, wherein the fluid injected during the injecting step is a chlorine based etching fluid.

8. A semiconductor device manufactured in accordance with the method of claim 1.

9. The method of claim 2, wherein the steps of providing a first sacrificial layer and a second sacrificial layer further comprise the step of:
depositing layers of sacrificial material using Plasma-Enhanced Chemical Vapour Deposition.

10. The method of claim 3, wherein the step of providing the structure further comprises the steps of:
depositing a layer of conductive material onto the first layer of sacrificial material using a DC Magnetron reactive sputter process; and
patterning the deposited layer.

11. The method of claim 10, wherein the step of patterning the deposited layer further comprises the steps of:
applying a photo-resist mask to the deposited layer;
etching the mask pattern into the deposited layer; and
removing the photo-resist mask layer.

12. The method of claim 10, wherein the conductive layer is a layer of Titanium Nitride (TiN).

13. The method claim 2, wherein the fluid injected during the injecting step is a chlorine based etching fluid.

14. The method claim 3, wherein the fluid injected during the injecting step is a chlorine based etching fluid.

15. The method claim 4, wherein the fluid injected during the injecting step is a chlorine based etching fluid.
